(19) United States
(12) Patent Application Publication
(10) Pub. No.: US 2026/0259268 A1
(43) Pub. Date: Sep. 3, 2026

(54) METHOD AND SYSTEM FOR EFFECTING AND DETERMINING A DEFECT ON A PEM FUEL CELL

(71) Applicant: AVL List GmbH, Graz (AT)

(72) Inventors: Tanner BRUHN, Graz (AT); Laurent ALLOUCHERY, Hart Bei Graz (AT)

(73) Assignee: AVL List GmbH, Graz (AT)

(21) Appl. No.: 18/875,228

(22) PCT Filed: Jul. 20, 2023
(86) PCT No.: PCT/AT2023/060244

§ 371 Date: Dec. 16, 2024

(30) Foreign Application Priority Data
Jul. 21, 2022 (AT) A 50546/2022

(51) Int. Cl. G01R 31/36; G01R 31/367; G01R 31/389; G01R 31/392; H01M 8/04298; H01M 8/0444; H01M 8/04492; H01M 8/04537; H01M 8/04664; H01M 8/10

(52) U.S. Cl. CPC G01R 31/3644; G01R 31/367; G01R 31/389; G01R 31/392; H01M 8/04305; H01M 8/04447; H01M 8/04492; H01M 8/04544; H01M 8/04664; H01M 2008/1095

(57) ABSTRACT

The present invention relates to a system (100) and method for inducing and determining a specific fault and/or impairment on a PEM fuel cell (10). In addition to a measurement of operating parameters, a comparison of measurement signals with reference signals and a determination of whether a specific fault and/or impairment is present, a control of operating parameters in a test operation is in particular carried out according to provided stress factor patterns in which critical settings and/or courses of operating parameters are stored for the purpose of inducing faults and/or impairments on the fuel cell under test (10).

The present invention relates to a method and a corresponding system for inducing and determining a fault and/or impairment on a PEM fuel cell.

The method and the system according to the invention are suitable for investigating malfunctions in and damage to low-temperature fuel cells with a polymer electrolyte membrane (PEM fuel cells). This allows the development of faults to be detected and investigated, allowing conclusions to be drawn regarding their avoidance or regarding the improvement of fuel cells.

Different measurement methods are known for carrying out measurements during operation or shutdown of a fuel cell or a fuel cell stack in the system environment in the application of the fuel cell as a power source, or also during its use. Signals are usually generated from the measurements which are analysed and thus allow conclusions to be drawn, indirectly, regarding an ageing condition or degradation of a fuel cell.

In a known measurement method for detecting degradation of a catalytic element of the fuel cell system, temperatures are measured which can provide an indirect indication of degradation. The temperature measurements which are used are processed into temperature datasets in order to calculate a temperature gradient for the inlet area of the catalytic element. In the second step of the method, a temperature gradient is compared with a reference parameter. In the last step, the degradation status is assessed on the basis of the comparison result.

In another known measurement method, in order to detect faults and/or degradation in a fuel cell array, an analysis of the power spectrum density (PSD) of a voltage signal output is carried out by the fuel cell array during stationary operation and specific fault and/or degradation signatures are identified from specific patterns achieved by the PSD of the measured voltage signal.

In yet another known measurement method, an analysis of a deterioration in the performance of a fuel cell is carried out. This involves measuring the AC impedance, which is compared with a reference value. Based on the result of this comparison, the deterioration in the performance of the fuel cell can be detected indirectly.

While the aforementioned measurement methods and their methodology can in some cases be integrated into a system environment of the application in order to provide monitoring of the ageing condition over the service life, the findings from this always refer to the individual use of a specific model of a fuel cell and the individual influences that the fuel cell or a corresponding fuel cell stack has experienced in its application and system environment over its service life. Combining the findings from the individual monitoring can involve considerable effort or can be impossible to access for an end user at the end of a service life and, accordingly, is associated with a considerable time horizon depending on the service life. In addition, a measurement technique or analysis must be adapted individually, and its findings cannot be readily transferred to other models of PEM fuel cells or their application.

Accordingly, there is a need for a technique for the universal investigation of specific faults on a structure or resulting impairments of performance which allows comparability among any model of PEM fuel cells or an empirical investigation of a specific fault within an acceptable time horizon.

It is an object of the invention to create a technique that allows for universal and reproducible investigations of faults in or impairment or degradation of PEM fuel cells. A further object of the invention is to implement these investigations automatically and within an acceptable time horizon in the context of product development.

The above objects are achieved by a system with the features of claim 1 and a method with the steps of claim 8. Further features and details of the invention are disclosed in the dependent claims, the description and the drawings. Naturally, features and details described in connection with the apparatus according to the invention also apply in connection with the method according to the invention and vice versa in each case, so that with regard to disclosure mutual reference is or can always be made to the individual aspects of the invention.

The system according to the invention is designed to induce and determine a specific fault and/or impairment on a PEM fuel cell. For this purpose, the system according to the invention has various system components. A measuring module for measuring at least one operating parameter of the fuel cell and for outputting a fingerprint pattern with a temporal signal course of a measurement signal comprises at least one sensor for registering the at least one operating parameter on the fuel cell. A comparison module is used to compare the signal course of the measurement signal from the output fingerprint pattern with a signal course of a reference signal from a reference pattern, wherein different reference patterns with signal courses of reference signals characteristic of different specific faults and/or impairments are provided in the comparison module. A determination module is used to determine whether the specific fault and/or impairment for which the signal course of the reference signal from the reference pattern used for comparison is characteristic has occurred, at least gradually, wherein the determination module is configured to base the determination on a common intersection between the signal courses of the measurement signal from the fingerprint pattern and the reference signal from the reference pattern.

According to the invention, the system includes a test bench module with a fuel gas test supply for supplying a fuel gas to an anode section of the fuel cell in a test operation and an oxidation gas test supply for supplying an oxidation gas to a cathode section of the fuel cell in the test operation, as well as an electrical test load for dissipating electrical power from the fuel cell in the test operation. In addition, a stress factor pattern is in particular provided in a control module for controlling operating parameters of the test operation of the fuel cell on the test bench module, in which pattern critical settings and/or critical courses of operating parameters are stored for the purpose of inducing faults and/or impairments on the fuel cell in the test operation.

Analogously, according to the invention, the corresponding method for inducing and determining a specific fault and/or impairment on a PEM fuel cell provides for the following steps: a step involving measuring at least one operating parameter of the fuel cell by registering the at least one operating parameter on the fuel cell by means of at least one sensor, and outputting a fingerprint pattern with a temporal signal course of a measurement signal. A step involving comparing the signal course of the measurement signal from the output fingerprint pattern with a signal course of a reference signal from a reference pattern by providing different reference patterns with signal courses of reference signals characteristic of different specific faults and/or impairments. A step involving determining whether the specific fault and/or the impairment for which the signal course of the reference signal from the reference pattern used for comparison is characteristic has occurred, at least gradually, wherein the determination is based on a common intersection between the signal courses of the measurement signal from the fingerprint pattern and the reference signal from the reference pattern.

According to the invention, a step is provided which involves carrying out a test operation on a test bench with a fuel gas test supply for supplying a fuel gas to an anode section of the fuel cell in a test operation and an oxidation gas test supply for supplying an oxidation gas to a cathode section of the fuel cell in the test operation, as well as an electrical test load for dissipating electrical power from the fuel cell in the test operation. In particular, controlling of operating parameters of the fuel cell test operation on the test bench is carried out in accordance with at least one stress factor pattern in which critical settings and/or progressions of the operating parameters over time are stored for the purpose of inducing faults and/or impairments on the fuel cell in the test operation.

The invention thus provides for the first time the combination of measurement and analysis technology with a universal test environment in which generic patterns are used to control a test operation for the controlled and preferably accelerated as well as reproducible ageing or degradation of fuel cells.

One advantage of the invention can be seen as the creation of a universal system and method for controlled uniform examination or testing of different models of PEM fuel cells which also enables an efficiently shortened long-term testing based on strenuous stress factor patterns.

The system or method can therefore be used very flexibly for different types, setups and sizes of PEM fuel cells and is above all of particular value for product development or experimental investigation.

As a further advantage of the invention, an automated detection of signs of ageing, such as slight or critical impairments of the performance, structure or integrity of a PEM fuel cell, is made possible in order to avoid complete malfunction due to known specific faults or types of damage.

Likewise, one advantage of the invention is that the system or method is supplied by the manufacturer or supplier with a selection of generic reference patterns with a base reference curve of the reference signal for a selection of known fault patterns which the system or method enables the customer to diagnose.

Under the term operating parameters, the present disclosure defines various control variables such as gas quantities, electrical power requirement or consumption, temperatures of reactants and resulting variables such as an output voltage or open circuit voltage of the fuel cell, or temperatures of products, chemical concentrations of individual substances in products, etc. which can be actively set or controlled in the test operation or which occur passively and can be measured.

Under the term measurement signal, the present disclosure defines a signal which directly reflects the value of a measured variable of a sensor or which can be derived indirectly from the measured variable.

Under the term fingerprint pattern, the present disclosure defines a curve course of a signal level of a measurement signal recorded over a period of time.

Under the term reference signal, the present disclosure defines a signal which is of the same type and significance as a measurement signal for which it is used for comparison.

Under the term reference pattern, the present disclosure defines a curve course of a signal level of the reference signal recorded over a period of time, whereby the curve course includes in particular characteristic sections such as inflection points, constants, upper and lower limit values or the like whose temporal relationship and deviation deviate from values and courses that would be usual for a new or undamaged fuel cell.

Under the term common intersection, the present disclosure defines common characteristic features of the curve courses of signals, such as a number of inflection points, an amplitude, a temporal behaviour such as an amplitude range, frequency or the like.

Under the term specific faults, the present disclosure defines typical types of damage to a structure of a fuel cell, such as thinning or damage, e.g. in the form of holes or cracks in a membrane, or deactivation of regions in a thickness or area of catalyst layers.

Under the term impairment, the present disclosure defines various reductions in the performance of the fuel cell with regard to parameters such as output voltage or output current in relation to input parameters of a supply of reactants, or a reduction in electrochemical or physical processes taking place in a fuel cell. In particular, the impairments may occur or be detected with gradually increasing frequency and may be a direct or indirect consequence of a specific fault in or damage to the structure of the fuel cell or other ageing phenomena.

Under the term stress factor pattern, the present disclosure defines a static or dynamic characteristic map of stored operating parameters with control variables such as gas quantities, electrical power requirement or consumption, temperatures of reactants, or a static or dynamic characteristic map of target values of resulting variables such as an output voltage or open circuit voltage of the fuel cell.

Under the term critical setting or critical courses of operating parameters, the present disclosure defines absolute values whose average duration or dynamic change, such as in particular cyclic high output voltages or open circuit voltages, are chosen in such a way that they result in a reproducible test operation on the fuel cell under test which, according to technical knowledge, results in extreme stress and a rapid initiation of ageing effects.

According to an advantageous aspect of the invention, the at least one stress factor pattern can have a cyclic course of operating parameters to achieve a cyclic course of an output voltage of the fuel cell with defined voltage peaks. Accordingly, a load on the fuel cell with a defined number of voltage peaks or defined total duration at in-creased voltage plateaus of the output voltage or open circuit voltage of the fuel cell can be achieved over a period of test operation which triggers damage to the fuel cell structure in an adjustable and reproducible manner.

According to an advantageous aspect of the invention, the signal courses of the measurement signal and the reference signal can be normalised to a common zero point and/or scale when comparing or determining a fault, and the common intersection can be determined based on an intersection of an amplitude range and/or an amplitude frequency of the normalised signal courses. In this way, the system or method is able to examine known fault patterns on the basis of pre-stored, generic reference patterns with a preset parameter value and temporal behaviour on any model of fuel cell with different parameter values and temporal behaviour.

According to an advantageous aspect of the invention, as a result of a determination that a specific fault or impairment is present, a diagnostic output signal can be output that includes a percentage diagnostic probability of the specific fault and/or impairment, the percentage of which is based on the intersection between the signal courses of the measurement signal and the reference signal.

According to an advantageous aspect of the invention, an editing of a provided reference pattern can be carried out based on an adjustment, specific to the fuel cell, of the signal course of the reference signal in the reference pattern to the signal course of the measurement signal of the fingerprint pattern for which it has been determined that the specific fault and/or impairment for which the signal course of the reference signal from the reference pattern is characteristic has occurred, at least gradually. Thus, in the universal system or method, a generic reference pattern can be customised customer-specifically in relation to a specific model under investigation in order to improve fault detection for the specific model.

According to an advantageous aspect of the invention, the system or method can further use a signal generator to apply an AC voltage-based excitation signal to the fuel cell, whereby the at least one sensor registers an AC voltage-based signal response resulting from an interaction between the excitation signal and the fuel cell. This technique allows the measurement methodology to be extended to include an AC impedance measurement by active signal excitation and passive signal response in order to examine a condition of the fuel cell.

Alternatively, according to one aspect of the invention, the measurement technology used in the system or the method can include a voltage sensor for registering the output voltage of the fuel cell, a hydrogen sensor for registering a hydrogen concentration on a cathode side of the fuel cell, a conductivity sensor for registering the conductivity in a product water discharged from the fuel cell, and/or a virtual sensor which is emulated based on indirect measurements of other physical sensors by means of a degradation model of an analysis software on the measuring module.

In addition, according to one aspect of the invention, the method according to the invention can be implemented in a computer program that carries out the steps in connection with the required hardware as contained in the system according to the invention.

Further advantages, features and details of the invention are explained in the following description, in which exemplary embodiments of the invention are described in detail with reference to the drawings. In each case schematically:

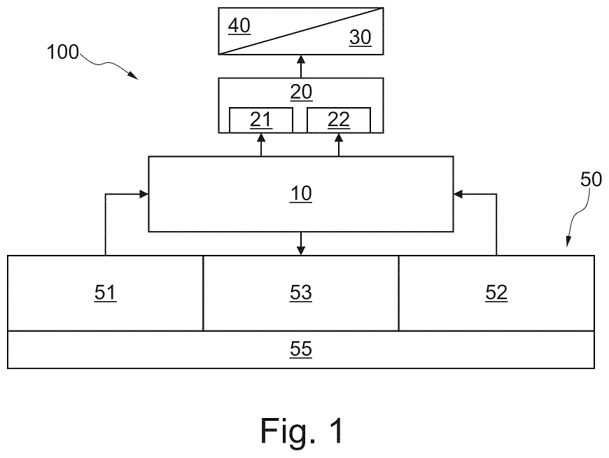

FIG. 1 shows a schematic block diagram of the system components in an embodiment of the system according to the invention,

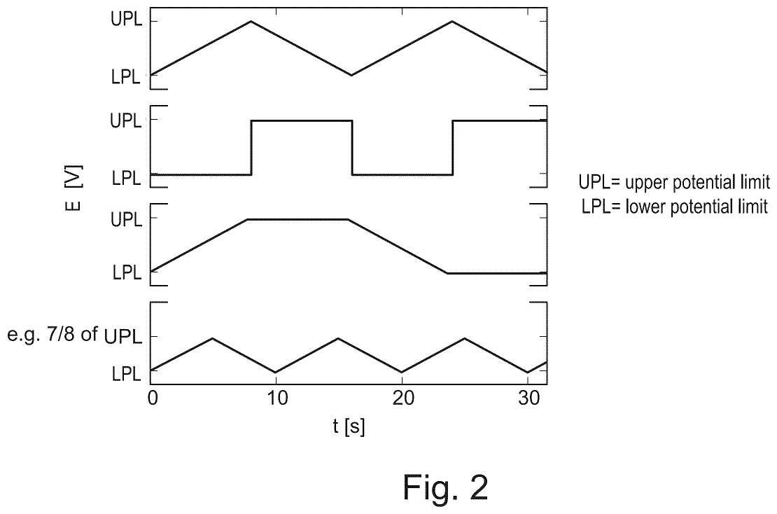

FIG. 2 shows a diagram showing different courses of an output voltage or open circuit voltage of a fuel cell under test which can be achieved by controlling the operating parameters on the basis of different stress factor patterns in test operation,

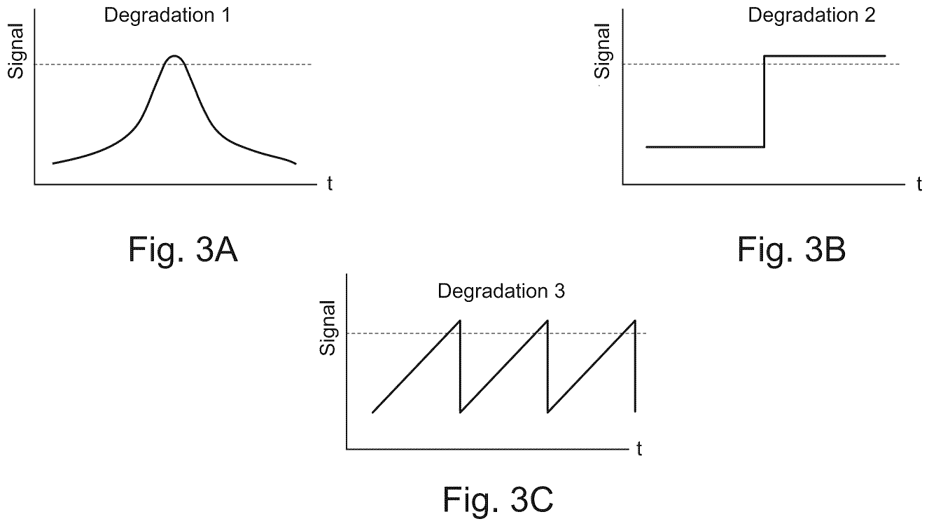

FIG. 3A shows a diagram of a measurement signal corresponding to a registration of a parameter on the fuel cell by a sensor, the course of which, as a fingerprint pattern, indirectly allows a conclusion to be drawn about a first type of degradation,

FIG. 3B shows a diagram of a measurement signal corresponding to a registration of a parameter on the fuel cell by a sensor, the course of which, as a fingerprint pattern, indirectly allows a conclusion to be drawn about a second type of degradation,

FIG. 3C shows a diagram of a measurement signal corresponding to a registration of a parameter on the fuel cell by a sensor, the course of which, as a fingerprint pattern, indirectly allows a conclusion to be drawn about a third type of degradation, and

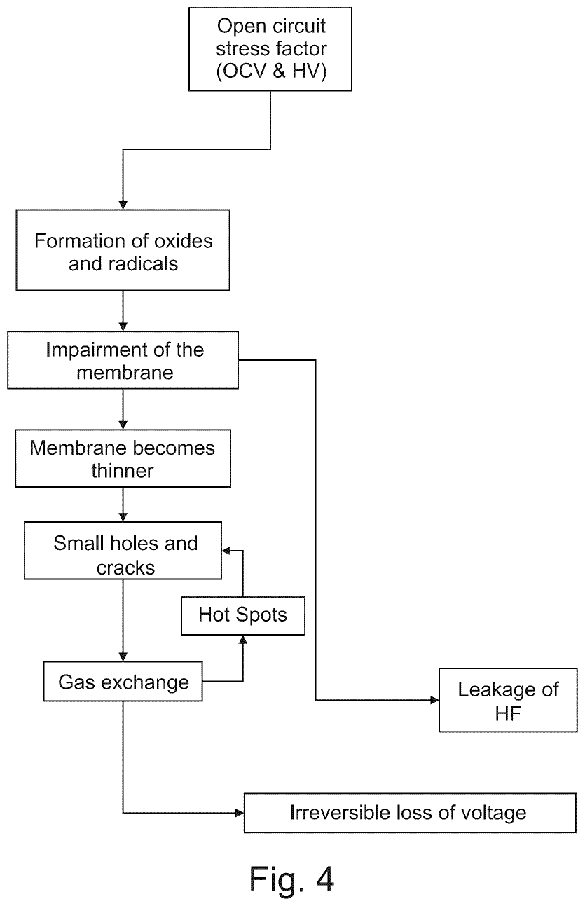

FIG. 4 shows a flowchart showing an exemplary chain of causes that leads to a specific fault on a fuel cell structure.

FIG. 1 shows schematically in a block diagram an embodiment of a structure of a system 100 for inducing and determining a specific fault and/or impairment on a PEM fuel cell 10. The system 100 includes, among other things, various modules as system components, which are explained below.

The fuel cell 10 or fuel cell stack to be examined or tested can be of any model or type of PEM fuel cell regarding which knowledge is to be gained in the context of a scientific investigation, fault analysis, product development or the like.

A test bench module 50 represents a test environment that enables operation of the fuel cell 10 to be tested under laboratory conditions. This includes a fuel gas test supply 51 with for example (not shown) a hydrogen gas tank, a control valve and a connection that is connected to an anode section of the fuel cell 10. Also an oxidation gas test supply 52 with for example (not shown) a compressor for supplying atmospheric oxygen, a control valve and/or speed control of the compressor and a connection connected to a cathode section of the fuel cell 10. In addition, a test load 53 with a controllable power consumption or demand is connected to the fuel cell 10 which is provided by a heat sink or an electromotive consumer. Adjustable actuators of the fuel gas test supply 51 and the oxidation gas test supply 52 as well as a circuit, in particular power electronics of the test load 53, are connected, together, to a control module 55, from which operating parameters for the test operation of the fuel cell 10 are controlled and regulated by means of signals.

Different general stress factor patterns are stored in the control module 55 which can be selected by a user in order to carry out, reproducibly, different stresses and ageing scenarios on the fuel cell 10 under test. The operating parameters in the test operation are controlled and regulated in accordance with the selected stress factor pattern, as will be explained later in connection with FIG. 2.

The system 100 also includes a measuring module 20 which represents different types of measurement technology. For example, the measuring module 20 includes at least one sensor 21 which registers an operating variable on the fuel cell 10. Preferably, several different types of sensors 21, such as a voltage sensor, a current sensor, a temperature sensor, a pressure sensor for a gas pressure, a concentration sensor for a concentration of hydrogen (H2) or hydrogen fluoride (HF), or a conductivity sensor for a conductivity in liquids are provided to examine the power output and supplied or discharged fluids.

In the embodiment shown, the system 100 also includes a signal generator 22 which, as part of a measurement technique for impedance spectroscopy, applies an excitation signal, for example an alternating current signal with frequency modulation, to the electrodes of the fuel cell 10, in conjunction with a voltage sensor 21 which registers a resulting signal response in interaction with the condition of the structure of the fuel cell 10.

The measuring module 20 converts the measured variable of a sensor 21 into a digital measurement signal that can be subjected to further data processing for analysis. For this purpose, a comparison module 30 and a determination module 40 are used which can be implemented as a software tool or subroutines of a computer program for the method.

General reference patterns are stored in the comparison module 30 which contain characteristic curve courses of relevant operating parameters that are directly or indirectly typical for the behaviour of a fuel cell 10 in the event of specific faults or damage. The comparison module 30 or alternatively the determination module 40 normalises the signal courses of the measurement signal and the reference signal which re-late to the same measured variable of an operating parameter to a common zero point and/or a common scale, so that commonalities of an absolute or qualitative curve course are more readily and universally comparable even with different types and dimensions of fuel cell 10. Depending on a degree of correspondence of characteristic features of the curve course that are selected as relevant for an indirect conclusion of a fault pattern, i.e. based on the amount of a common intersection of such commonalities (number of inflection points, absolute values, mean values or the like), the determination module 40 determines whether a specific fault has occurred. The determination module 40 also uses the amount of the intersection to determine the diagnostic probability that the fault has occurred. Alternatively or additionally, the de-termination module 40 determines how far the specific fault or a resulting impairment of the structure or performance of the fuel cell 10 has progressed based on the values in the intersection.

FIG. 2 shows different superimposed stress factor patterns for the test operation of a fuel cell 10 under test. More precisely, the diagram shows that exemplary types of cyclic control of operating parameters on the basis of different stress factor patterns in test operation induce different courses of an electric field between the electrodes in the fuel cell 10, which can be measured by means of the applied voltage.

For example, a triangular modulation, a rectangular wave modulation, a triangular wave modulation with a maintained potential level or a triangular wave modulation with reduced potential peaks is created which, based on empirical investigations, cause different reproducible rates of ageing or damage to the fuel cell structure in the endurance test.

FIGS. 3A, 3B and 3C show diagrams of exemplary fingerprint patterns that deviate from a usual behaviour or signal course of a new or undamaged cell, taking into account the predetermined course of the operating parameters in test operation. FIGS. 3A, 3B and 3C illustrate different measurement signals corresponding to the measured variables of different types of sensors 21 with regard to relevant operating parameters for which a characteristically deviating behaviour is known in connection with particular fault patterns of specific faults, for example a thinning of or damage to the membrane or a reduction of an active catalyst material.

In order to illustrate the development of a form of damage to the fuel cell structure, FIG. 4 shows an exemplary chain of causes leading to the specific fault of membrane damage.

In a test operation, based on a stress factor pattern, cyclically determined levels and holding times of an open circuit voltage (OCV) or high output voltage (HV) are for example induced in the fuel cell 10 by throttling the power consumption from the test load 53 while supplying the reaction gases via the fuel gas test supply 51 and the oxidation gas test supply 52. The high voltages in the fuel cell 10 encourage harmful electrochemical processes such as the formation of hydrogen peroxide or free radical species which gradually attack the substance of the polymer electrolyte membrane. As time goes on, the membrane becomes thinner, so that its integrity is compromised. After that, small holes and finally cracks appear, as a result of which a gas exchange between the anode and the cathode is no longer hindered. The gas exchange leads to local exothermic reactions or hot spots, which in turn lead to further consequential damage to the membrane and other structures such as the catalytic material.

Depending on the measurement technology used in the measuring module 20, the different stages of damage or of a specific fault, such as a thinning of the membrane, can be detected in advance by means of suitable sensors. For example, an impending impairment of the membrane is characterised by the release of hydrogen fluoride (HF) or, at a later stage, hydrogen (H2) in the product water, which can be detected by a suitable concentration measurement or conductivity measurement in the product water. A comparison, evaluated as a fingerprint pattern of the corresponding measurement signal, with a reference pattern containing characteristic values and/or courses with regard to the HF concentration or H2 concentration, or a conductivity of the product water indirectly associated with this, leads to an automated determination of a fault status during test operation. At a later stage, the same measurement methodology can also be used to detect the specific fault on the basis of a voltage loss.

The above explanations of the embodiments describe the present invention exclusively in the context of examples.

### LIST OF REFERENCE SIGNS

10 fuel cell
20 measuring module
21 sensor
22 signal generator
30 comparison module
40 determination module
50 test bench module
51 fuel gas supply
52 oxidation gas supply
53 test load
55 control module
100 system

1. System for inducing and determining a specific fault and/or impairment on a PEM fuel cell comprising:
a measuring module for measuring at least one operating parameter of the fuel cell and for outputting a fingerprint pattern with a temporal signal course of a measurement signal, comprising at least one sensor for registering the at least one operating parameter on the fuel cell;
a comparison module for comparing the signal course of the measurement signal from the output fingerprint pattern with a signal course of a reference signal from a reference pattern, wherein different reference patterns with signal courses of reference signals characteristic of different specific faults and/or impairments are provided in the comparison module;
a determination module for determining whether the specific fault and/or impairment for which the signal course of the reference signal from the reference pattern used for comparison is characteristic has occurred, at least gradually, wherein the determination module is configured to base the determination on a common intersection between the signal courses of the measurement signal from the fingerprint pattern and the reference signal from the reference pattern;
wherein the system further comprises:
a test bench module with a fuel gas test supply for supplying a fuel gas to an anode section of the fuel cell in a test operation and an oxidation gas test supply for supplying an oxidising gas to a cathode section of the fuel cell in the test operation, as well as an electrical test load for dissipating electrical power from the fuel cell in the test operation;
a control module for controlling operating parameters of the test operation of the fuel cell on the test bench module, wherein at least one stress factor pattern is provided in the control module, in which pattern settings and/or critical courses of operating parameters are stored for the purpose of inducing faults and/or impairments on the fuel cell in the test operation.

2. System according to claim 1, wherein the at least one stress factor pattern provided in the control module has a cyclic progression of operating parameters to achieve a cyclic progression of an output voltage of the fuel cell with defined voltage peaks.

3. System according to claim 1, wherein the comparison module and/or the determination module is configured to normalise the signal courses of the measurement signal and the reference signal to a common zero point and/or scale, and to determine the common intersection based on an intersection of an amplitude range and/or an amplitude frequency of the normalised signal courses.

4. System according to claim 1, further comprising a diagnostic output module for the output of a diagnostic output signal comprising a percentage diagnostic probability with respect to the specific fault and/or impairment, the percentage of which is based on the intersection between the signal courses of the measurement signal and the reference signal.

5. System according to claim 1, further comprising an editing module for editing a provided reference pattern based on an adjustment, specific to the fuel cell, of the signal course of the reference signal in the reference pattern to the signal course of the measurement signal of the fingerprint pattern for which it has been determined that the specific fault and/or the impairment for which the signal course of the reference signal from the reference pattern is characteristic has occurred, at least gradually.

6. System according to claim 1, wherein the measuring module further comprises a signal generator for applying an AC voltage-based excitation signal to the fuel cell, wherein the at least one sensor registers an AC voltage-based signal response resulting from an interaction between the excitation signal and the fuel cell.

7. System according to claim 1, wherein the at least one sensor of the measuring module is
a voltage sensor for registering the output voltage of the fuel cell,
a hydrogen sensor for registering a hydrogen concentration on a cathode side,
a conductivity sensor for registering the conductivity of a product water, and/or
a virtual sensor that is emulated by means of a degradation model of an analysis software on the measuring module.

8. Method for inducing and determining a specific fault and/or impairment on a PEM fuel cell, comprising the following steps:
measuring at least one operating parameter of the fuel cell by registering the at least one operating parameter on the fuel cell by means of at least one sensor, and outputting a fingerprint pattern with a temporal signal course of a measurement signal;
comparing the signal course of the measurement signal from the output fingerprint pattern with a signal course of a reference signal from a reference pattern by providing different reference patterns with signal courses of reference signals characteristic of different specific faults and/or impairments;
determining whether the specific fault and/or impairment for which the signal course of the reference signal from the reference pattern used for comparison is characteristic has occurred, at least gradually, wherein the determination is based on a common intersection between the signal courses of the measurement signal from the fingerprint pattern and the reference signal from the reference pattern;
wherein the steps
carrying out a test operation on a test bench with a fuel gas test supply for supplying a fuel gas to an anode section of the fuel cell in a test operation and an oxidation gas test supply for supplying an oxidation gas to a cathode section of the fuel cell in the test operation, as well as an electrical test load for dissipating electrical power from the fuel cell in the test operation; and
controlling operating parameters of the test operation of the fuel cell on the test bench in accordance with at least one stress factor pattern in which settings and/or progressions of the operating parameters over time are stored for the purpose of inducing faults and/or impairments on the fuel cell in the test operation.

9. Method according to claim 8, wherein at least one stress factor pattern has a cyclic progression of operating parameters to achieve a cyclic progression of an output voltage of the fuel cell with defined voltage peaks.

10. Method according to claim 8, wherein the step of comparing and/or determining further comprises the following intermediate steps:
normalising the signal courses of the measurement signal and the reference signal to a common zero point and/or scale; and
determining the common intersection based on an intersection of an amplitude range and/or an amplitude frequency of the normalised signal courses.

11. Method according to one of the claim 8, further comprising the step:
outputting a diagnostic output signal that includes a percentage diagnostic probability of the specific fault and/or impairment, the percentage of which is based on the intersection between the normalised signal courses of the measurement signal and the reference signal.

12. Method according to one of the claim 8, further comprising the step:
editing a provided reference pattern based on an adjustment, specific to the fuel cell, of the signal course of the reference signal in the reference pattern to the signal course of the measurement signal of the fingerprint pattern for which it has been determined that the specific fault and/or the impairment for which the signal course of the reference signal from the reference pattern is characteristic has occurred, at least gradually.

13. Method according to one of the claim 8, wherein the step of measuring further comprises the following intermediate steps:
applying an AC voltage-based excitation signal to the fuel cell by means of a signal generator; and
registering an AC voltage-based signal response resulting from an interaction between the excitation signal and the fuel cell by means of the at least one sensor.

14. Method according to one of the claim 8, wherein the step of measuring further comprises at least one of the following intermediate steps:
registering the output voltage of the fuel cell by means of a voltage sensor,
registering a hydrogen concentration on a cathode side by means of a hydrogen sensor,
registering the conductivity of a product water by means of a conductivity sensor, and/or
emulating a virtual sensor by means of a degradation model of an analysis software on the measuring module.

15. Computer program comprising commands which, when the computer program is run on a computer, cause this to carry out the steps of the method according to one of the claim 8.
